(19) United States
(12) Patent Application Publication
(10) Pub. No.: US 2008/0240296 A1
(43) Pub. Date: Oct. 2, 2008

(54) Iterative sequential carrier acquisition

(75) Inventor: Alan K. Hunt, Dallas, TX (US)

Correspondence Address: DOCKET CLERK, P.O. DRAWER 800889, DALLAS, TX, 75380, US

(73) Assignee: Crane Co., Stamford, CT (US)

(21) Appl. No.: 11/728,784

(22) Filed: Mar. 27, 2007

(51) Int. Cl. H04L 27/00; H03D 3/24

(52) U.S. Cl. 375/326; 375/327

(57) ABSTRACT

A system and method for iterative sequential carrier acquisition for estimating and correcting large carrier frequency offsets without adding significantly to receiver complexity or preamble length. A coarse frequency estimation is performed during a brief carrier acquisition phase that is completed during a reasonably short preamble, and then the system hands frequency control to the nominal carrier frequency & phase tracking of a phase-locked loop (PLL) circuit. The present disclosure generally includes an initialization mode, a pre-lock scan mode, an iterative search mode and a termination mode.

### TECHNICAL FIELD

This disclosure is generally directed to wireless data communication networks and more particularly to systems and methods for estimating and correcting large carrier frequency offsets.

### BACKGROUND

In conventional wireless data communication networks, clock frequency variations among members of the network produce carrier frequency offsets that may approach the same order of magnitude as symbol rates, resulting in high symbol error rates.

Conventional methods typically implement parallel hardware such as, for example, a channelized bank of matched filters spanning the expected range of frequency offset. The difference in center frequencies of the filter bank is selected to be less than the lock range of the phase-locked loop (PLL) circuit. The frequency of the filter channel yielding maximum energy is the frequency to which the digital downconverter should be tuned for coarse translation prior to the PLL. Accordingly, such conventional methods require the addition of certain hardware to implement the parallel filter bank.

Other conventional methods employ a Fast Fourier Transform (FFT) that interrogates the entire frequency span collected by the input time-sampling process. The time series is first windowed to minimize boundary-related artifacts, transformed, and then converted to a power spectrum. A series of successive power spectra may be averaged to improve the overall spectral estimate. The frequency of the peak-energy spectrum bin is the frequency to which the digital downconverter should be tuned for coarse translation prior to the PLL. Such conventional methods require relatively less hardware to implement.

Still other conventional methods implement a sequential filter bank with a single downconverter and matched filter that is time shared across the frequency-offset search range by applying an FM sweep to the local digital oscillator. The sweep is terminated and held when the energy detector declares a detected peak. Such conventional methods limit hardware complexity, but require a significant increase in preamble time to acquire a lock.

There is therefore a need for an improved system and method for estimating and correcting large carrier frequency offsets without significantly increasing receiver hardware complexity or preamble length.

### SUMMARY

This disclosure provides a system and method for estimating and correcting large carrier frequency offsets without significantly increasing receiver complexity or preamble length. Thus, the systems and methods according to embodiments of the present disclosure increase reliability with respect to decoding headers and payloads.

In one embodiment, the present disclosure provides a method of sequential carrier acquisition. The method includes varying a downconverter frequency through a sequence of frequencies. The method also includes synchronizing changes in the downconverter frequency with incoming symbols. The method further includes iteratively updating a frequency estimate associated with the incoming symbols and decreasing a search step size until convergence occurs.

In another embodiment, the present disclosure provides a method of sequential carrier acquisition in a receiver for use in a communication network. The method includes initializing a receiver and setting an initial frequency step size based on a previously determined nominal value. The method also includes varying a downconverter frequency through a sequence of frequencies beginning with the initial frequency step size. The method further includes synchronizing changes in the downconverter frequency with incoming symbols. The method still further includes iteratively updating a frequency estimate associated with the incoming symbols and decreasing the frequency step size until convergence occurs.

In another embodiment, the present disclosure provides a receiver for use in a communications network. The receiver includes a circuit configured to vary a downconverter frequency through a sequence of frequencies. The circuit may also synchronize downconverter frequency changes with incoming symbols. The circuit may further iteratively update a frequency estimate associated with the incoming symbols and decrease a search step size until convergence occurs.

Other technical features may be readily apparent to one skilled in the art from the following figures, descriptions and claims.

### BRIEF DESCRIPTION OF THE DRAWINGS

For a more complete understanding of this disclosure and its features, reference is now made to the following description, taken in conjunction with the accompanying drawings, in which:

FIG. 1 illustrates a relationship between the downconverter frequency and the carrier frequency estimate during the pre-lock scan, iterative search and PLL tracking modes according to one embodiment of the present disclosure; and

FIG. 2 is a somewhat simplified flow diagram illustrating a method according to one embodiment of the present disclosure.

### DETAILED DESCRIPTION

The present disclosure provides a system and method for estimating and correcting large carrier frequency offsets without adding significantly to receiver complexity or preamble length. Embodiments of the present disclosure perform coarse frequency estimation during a brief carrier acquisition phase that is completed during a reasonably short preamble, and then hands frequency control to the nominal carrier frequency & phase tracking of a phase-locked loop (PLL) circuit.

The system and method according to one embodiment of the present disclosure generally includes an initialization mode, a pre-lock scan mode, an iterative search mode and a termination mode for a receiver in any suitable communication system. In one embodiment, the communication system may be any suitable wireless communication system.

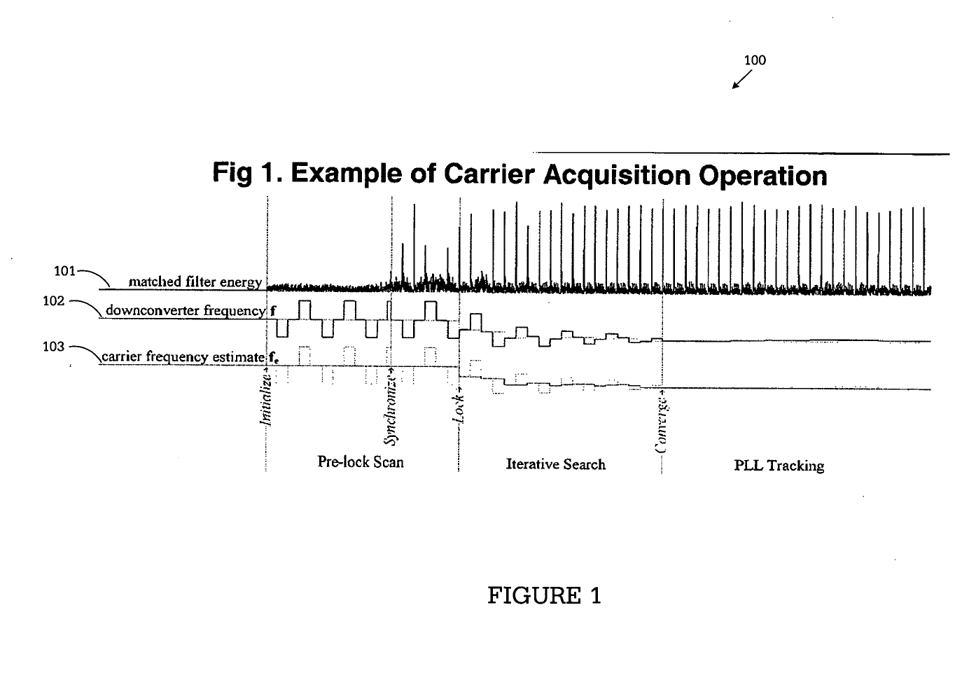

FIG. 1 displays relevant signals for an exemplary carrier acquisition operation during an incoming message with significant negative carrier frequency offset. For example, FIG. 1 generally illustrates relationship 100 between the matched filter energy 102, downconverter frequency (f) 104 and the carrier frequency estimate (fₑ) 106 during various modes of a. The receiver may in operating in a pre-lock scan mode 108, an iterative search mode 110 or a PLL tracking mode 112 according to one embodiment of the present disclosure.

### Initialization Mode:

In the initialization mode, the initial value of the frequency estimate (fₑ) is set to the nominal value, i.e., a value obtained from the frequency tracking PLL during a previous successfully received message. Then, the initial search step size or initial frequency step size (fₛ) is set to a large initial value (fₛ₀). Next, the nominal carrier frequency tracking PLL is disabled, but other nominal receiver functions continue to run. In FIG. 1, the receiver is initialized at point 114.

### Pre-Lock Scan Mode:

In the pre-lock scan mode 108, the downconverter frequency (f) is varied in a repeating sequence of frequencies separated by a relatively large initial frequency step size (fₛ₀). The system dwells at each frequency for one symbol period, aligning dwell periods with actual symbols as detections occur. The system then repeats until the receiver locks onto a sufficiently reliable sequence of detected symbols. This occurs at lock point 118 and the receiver disables the automatic gain control on the input signal.

### Iterative Search Mode:

In iterative search mode 110, after each symbol detection, the system calculates the frequency centroid (f_{c}) based on the 3-symbol history of downconverter frequency {f₁,f₂,f₃} and received energy {e₁,e₂,e₃}, as shown by the relationship exemplified by Equation 1 below.

f_{c}=(f₁×e₁+f₂×e₂+f₃×e₃)÷(e₁+e₂+e₃) (Eqn. 1)

Then, based on direct phase measurements from the running detector/decoder, the system calculates the current phase drift per symbol (dp) and scales it using a factor (k) to obtain an estimate of the current frequency offset (f_{dp}) as shown by the relationship exemplified in Equation 2 below.

f_{dp}=k×dp (Eqn. 2)

The system then updates the frequency estimate (fₑ) using an adaptively weighted combination of (f_{c}), (f_{dp}), and the previous value of (fₑ) (designated as fₑ₁) using the relationship exemplified by Equation 3 below.

fₑ=(a_{c}×f_{c}+a_{dp}×f_{dp}+aₑ₁×fₑ₁) (Eqn. 3)

After calculating (fₑ), weighting coefficients (a_{c}, a_{dp}, aₑ₁) take adaptive values reflecting the varying relative reliability of the frequency estimates (f_{c}, f_{dp}, fₑ₁) with the scale preserving constraint as shown by the relationship exemplified by Equation 4 below.

a_{c}+a_{dp}+aₑ₁=1 (Eqn. 4)

If certain criteria have been met, the system then decreases the frequency step size (fₛ) depending upon a measure of convergence. For example, in one embodiment, the system may update the current frequency in a sequence that includes combinations of iteratively updated values of fₑ and fₛ. For example, the sequence may be: {fₑ₁, fₑ₁+fₛ₁, fₑ₂, fₑ₂−fₛ₂, fₑ₃, fₑ₃+fₛ₃, fₑ₄, fₑ₄−fₛ₄, . . . }.

As the step size is decreased, the system approaches the correct frequency. For example, the system repeats the above-described steps in the iterative mode until convergence or timeout as exemplified by convergence point 120. Convergence 120 occurs when the frequency step size (fₛ) is sufficiently small, or when symbols are being decoded with sufficient reliability. Accordingly, the step size is decreased until the correct frequency is finally realized.

### Termination Mode or PLL Tracking Mode:

At convergence or timeout 120, the system re-enables the automatic gain control and the nominal frequency tracking PLL. In a preferred embodiment of the disclosure, the system includes a receiver in a direct sequence spread spectrum communication network, detecting symbols using a matched filter.

In FIG. 1, signals are displayed during an interval starting about 10 symbol periods before the 1^{st} symbol and ending after the 48^{th} symbol of the message. In one embodiment, initialization mode occurs about 10 symbol periods prior to arrival of the first symbol as shown in FIG. 1. The pre-lock scan mode 108 runs from initialization point 114 until receiver lock point 116, for about 17 symbol periods. Symbol synchronization point 116 occurs at the detection of the first received symbol, about 10 symbol periods after initialization point 114, and 6 symbol periods prior to receiver lock point 118. Receiver lock point 118 occurs at the detection of the 7^{th} received symbol. Iterative search mode 110 runs from receiver lock point 116 until convergence point 120, for 18 symbol periods. Convergence point 120 occurs at the detection of the 25^{th} received symbol. PLL tracking mode 112 runs continuously from convergence point 120 until the end of the received message. Thus, it should be understood that at every symbol, an embodiment of the present disclosure generates a frequency estimation.

According to one embodiment of the present disclosure, hardware complexity is limited by using the same single downconverter and matched filter that is used during the subsequent PLL-tracked header and payload decoding phase. The only addition to the nominal receiver is a fairly simple finite state machine used to execute an iterative frequency search for maximum energy and optimum symbol detection.

Accordingly, embodiments of the present disclosure use adaptive decreasing step size to determine a relatively precise optimum frequency over a wide frequency range in relatively few steps, e.g., requiring less than one third the time needed for an equivalent linear scan of the same range.

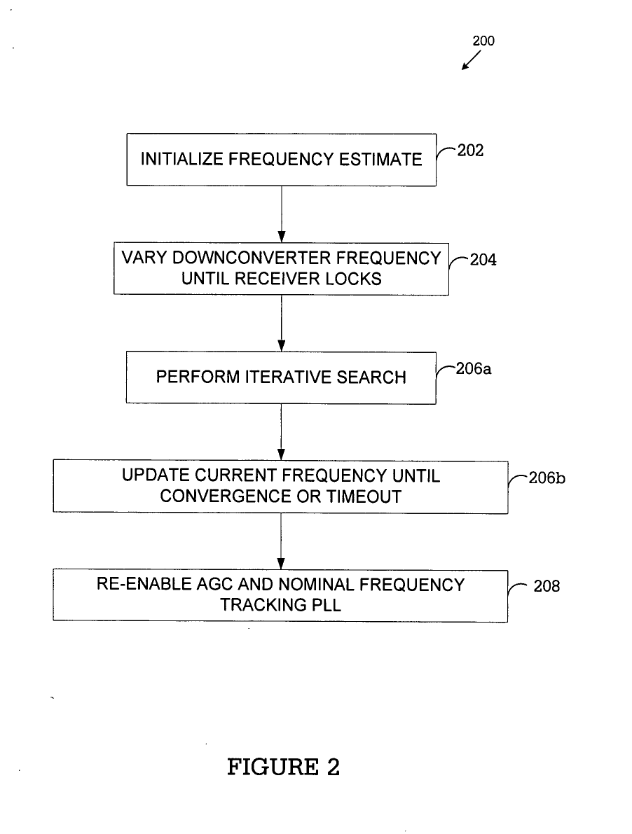

FIG. 2 is a somewhat simplified block diagram illustrating method 200 according to one embodiment of the present disclosure. Method 200 generally includes an initialization stage at step 202, a pre-lock scan stage at step 204, an iterative search stage at step 206, and finally a termination stage at step 208.

Step 202 includes setting the initial value of the frequency estimate (fₑ) to a nominal value. For example, the nominal value may be a value obtained from the frequency tracking PLL during a previous message that was successfully received. The initial frequency step size (fₛ) is set to a large initial value (fₛ₀). The nominal carrier frequency tracking PLL is disabled but all other nominal receiver functions are run as normal.

Step 204 includes varying the downconverter frequency f in a repeating sequence of frequencies. For example, the repeating sequence of frequencies may be separated by a relatively large initial frequency step size (fₛ₀). In one embodiment, method 200 remains or dwells at each frequency for one symbol period and aligns the dwell periods with the actual symbols as each detection occurs. Step 204 is generally repeated until the receiver locks onto a sufficiently reliable sequence of detected symbols. When this occurs, method 200 disables the automatic gain control (AGC) on the input signal.

Step 206a includes performing an iterative search, taking one step after each symbol detection. For example, step 206a includes calculating the frequency centroid based on a three-symbol history of the downconverter frequency and received energy. In one embodiment, for example, the frequency centroid may be realized using the relationship exemplified by Equation 1 described earlier herein.

Step 206a may also include calculating the current phase drift per symbol (dp) and scaling the current phase drift per symbol to obtain an estimate of the current frequency offset (f_{dp}). In one embodiment, for example, the current frequency offset (f_{dp}) may be realized using the relationship exemplified by Equation 2 described earlier herein.

Step 206b includes updating the frequency estimate (fₑ) using an adaptively weighted combination of f_{c}, f_{dp}, and the previous value of frequency estimate (fₑ) (designated as fₑ₁). In one embodiment, for example, the frequency estimate (fₑ) may be updated using the relationship exemplified by Equations 3 and 4 described earlier herein.

Finally, step 208 may include decreasing the frequency step size (fₛ) and updating the current frequency in a sequence based on iteratively updated values of fₛ and fₑ. In one embodiment, for example, the sequence may be given by: {fₑ₁, fₑ₁+fₛ₁, fₑ₂, fₑ₂−fₛ₂, fₑ₃, fₑ₃+fₛ₃, fₑ₄, fₑ₄−fₛ₄, . . . }.

It should be understood that method 200 preferably performs step 208 until convergence or timeout. In one embodiment, convergence occurs when frequency step size (fₛ) is sufficiently small or when symbols are decoded with sufficient reliability. After convergence, in step 210, method 200 re-enables the automatic gain control (AGC) and the nominal frequency tracking PLL.

Accordingly, in one embodiment, method 300 rapidly narrows the search range to frequencies that are relatively near the correct value. Thus, the nominal receiver performs well while running simultaneously with any carrier acquisition search. Thus, method 300 provides rapid receiver lock and thus allows time and phase information from the detector to be used in carrier acquisition prior to PLL handoff.

It should also be understood that method 200 may be accomplished by a receiver having any suitable circuit or circuits configured to perform the steps of method 200. In one embodiment, the present disclosure provides a system and method for generally replacing conventional frequency sweeps. The system and method requires using an adaptive decreasing step size to determine a relatively precise optimum frequency over a wide frequency range. Accordingly, the present disclosure requires less than one third of the time needed for an equivalent conventional sweep of the same range.

It may be advantageous to set forth definitions of certain words and phrases used in this patent document. The term “couple” and its derivatives refer to any direct or indirect communication between two or more elements, whether or not those elements are in physical contact with one another. The terms “include” and “comprise,” as well as derivatives thereof, mean inclusion without limitation. The term “or” is inclusive, meaning and/or. The phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like.

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A method of sequential carrier acquisition, the method comprising:
varying a downconverter frequency through a sequence of frequencies;
synchronizing changes in the downconverter frequency with incoming symbols; and
iteratively updating a frequency estimate associated with the incoming symbols and decreasing a search step size until convergence occurs.

2. The method of claim 1, wherein the synchronized downconverter changes are related to a previous frequency estimate and the search step size.

3. The method of claim 1 further comprising:
adjusting the search step size based on an iteratively evaluated reliability measure.

4. The method of claim 1, wherein the frequency estimate is based on frequency centroids.

5. The method of claim 4, wherein the frequency centroid is based on a three-symbol history of the downconverter frequency and a received energy.

6. The method of claim 1 further comprising:
obtaining an initial frequency estimate from a phase-locked loop (PLL) run during a previous message received in the receiver.

7. The method of claim 1, wherein the varying further comprises disabling a nominal carrier frequency tracking from a phase-locked loop (PLL).

8. The method of claim 1, wherein the iteratively updating further comprises disabling an automatic gain control on an input signal associated with the incoming symbols.

9. The method of claim 1, wherein the iteratively updating further comprises using a weighted combination of the frequency centroid, scaled symbol phase drift, and a previous value of the frequency estimate.

10. For use in a communication network, a method of sequential carrier acquisition in a receiver, the method comprising:
initializing a receiver and setting an initial frequency step size based on a previously determined nominal value;
varying a downconverter frequency through a sequence of frequencies beginning with the initial frequency step size;
synchronizing changes in the downconverter frequency with incoming symbols; and
iteratively updating a frequency estimate associated with the incoming symbols and decreasing the frequency step size until convergence occurs.

11. The method of claim 10, wherein the synchronized downconverter changes comprise combinations of the updated values of the frequency estimate and the updated values of the frequency step size.

12. The method of claim 10 further comprising:
adjusting the frequency step size based on an iteratively evaluated reliability measure.

13. The method of claim 10, wherein the frequency estimate is based on frequency centroids.

14. The method of claim 13, wherein the frequency centroids are based on a three-symbol history of the downconverter frequency and a received energy.

15. The method of claim 10 further comprising:
obtaining an initial frequency estimate from a phase-locked loop (PLL) run during a message previously received by the receiver.

16. The method of claim 10, wherein the varying further comprises disabling a nominal carrier frequency tracking from a phase-locked loop (PLL).

17. The method of claim 10, wherein the iteratively updating further comprises disabling an automatic gain control on an input signal associated with the incoming symbols.

18. The method of claim 10, wherein the iteratively updating further comprises using a weighted combination of the frequency centroid, scaled symbol phase drift, and a previous value of the frequency estimate.

19. For use in a communications network, a receiver comprising:
a circuit configured to vary a downconverter frequency through a sequence of frequencies, to synchronize downconverter frequency changes with incoming symbols, and to iteratively update a frequency estimate associated with the incoming symbols and decrease a search step size until convergence occurs.

20. The receiver of claim 19, wherein the frequency estimate is a weighted combination of the frequency centroid, scaled symbol phase drift, and a previous value of the frequency estimate.
